(19) United States
(12) Patent Application Publication
(10) Pub. No.: US 2026/0076244 A1
(43) Pub. Date: Mar. 12, 2026

(54) METHOD AND AN APPARATUS FOR FORMING AN ELECTRONIC DEVICE

(71) Applicant: JCET STATS ChipPAC Korea Limited, Incheon (KR)

(72) Inventors: YeoJun YUN, Incheon (KR); SeungHyun LEE, Incheon (KR); MinSung LEE, Incheon (KR); HeeSoo LEE, Incheon (KR)

(21) Appl. No.: 19/324,150

(22) Filed: Sep. 10, 2025

(30) Foreign Application Priority Data
Sep. 11, 2024 (CN) 202411270472.9

(51) Int. Cl. H01L 23/00

(52) U.S. Cl. CPC H10W 72/072; H10W 72/0711; H10W 72/016; H10W 72/07125; H10W 72/07141; H10W 72/07235; H10W 72/07236

(57) ABSTRACT

A method and an apparatus for forming an electronic device is provided. The method comprises: providing a substrate; disposing at least one electronic component on the substrate via a solder paste; applying an inert atmosphere to the substrate and the solder paste, wherein the inert atmosphere has a reduced oxygen partial pressure compared with air atmosphere; and reflowing the solder paste by a heating process within the inert atmosphere to reduce voids formed within the solder paste during the reflowing of the solder paste.

### TECHNICAL FIELD

The present application generally relates to semiconductor technology, and more particularly, to a method and an apparatus for forming an electronic device.

### BACKGROUND OF THE INVENTION

The semiconductor industry is constantly faced with complex integration challenges as consumers want their electronics to be smaller, faster and higher performance with more and more functionalities packed into a single device. Typically, electronic components are mounted onto a substrate via solder bumps. The solder bumps may be formed by conducting a heating process to reflow a solder paste disposed between the substrate and the electronic components, which enables efficient electrical connection between the substrate and the electronic components thereon. However, the formed solder bumps may have void defects after the heating process, especially for a rapid heating and cooling process using laser heating technique. This may adversely affect bonding performance between the substrate and the electronic components.

Therefore, a need exists for a method for forming an electronic device.

### SUMMARY OF THE INVENTION

An objective of the present application is to provide a method for forming an electronic device with an improved bonding quality between a substrate and an electronic component via solder bumps with reduced voids.

According to an aspect of the present application, a method for forming an electronic device is provided. The method comprises: providing a substrate; disposing at least one electronic component on the substrate via a solder paste; applying an inert atmosphere to the substrate and the solder paste, wherein the inert atmosphere has a reduced oxygen partial pressure compared with air atmosphere; and reflowing the solder paste by a heating process within the inert atmosphere to reduce voids formed within the solder paste during the reflowing of the solder paste.

According to another aspect of the present application, an apparatus for forming an electronic device is provided. The apparatus comprising: a platform configured for placing a substrate, wherein the substrate is disposed with at least one electronic component via a solder paste; a heating device configured for heating the substrate and the solder paste to reflow the solder paste; and a reflowing chamber disposed on the platform and configured for reflowing the solder paste when the substrate is disposed within the reflowing chamber; a vacuum source in communication with the reflowing chamber and configured for applying a vacuum pressure to the substrate and the solder paste when the substrate is disposed within the reflowing chamber; and a gas supply in communication with the reflowing chamber and configured for applying an inert gas to the substrate and the solder paste when the substrate is disposed within the reflowing chamber, wherein the vacuum pressure and the inert gas applied to the solder paste and the substrate reduce voids formed within the solder paste during the reflowing of the solder paste within the reflowing chamber.

It is to be understood that both the foregoing general description and the following detailed description are exemplary and explanatory only, and are not restrictive of the invention. Further, the accompanying drawings, which are incorporated in and constitute a part of this specification, illustrate embodiments of the invention and together with the description, serve to explain the principles of the invention.

### BRIEF DESCRIPTION OF DRAWINGS

The drawings referenced herein form a part of the specification. Features shown in the drawing illustrate only some embodiments of the application, and not of all embodiments of the application, unless the detailed description explicitly indicates otherwise, and readers of the specification should not make implications to the contrary.

FIGS. 1A to 1D illustrate various steps of a method for forming an electronic device according to a first embodiment of the present application.

FIG. 2 illustrates a reflowing step of a solder paste during a method for forming an electronic device according to a second embodiment of the present application.

FIG. 3 illustrates an apparatus for forming an electronic device according to a third embodiment of the present application.

The same reference numbers will be used throughout the drawings to refer to the same or like parts.

### DETAILED DESCRIPTION OF THE INVENTION

The following detailed description of exemplary embodiments of the application refers to the accompanying drawings that form a part of the description. The drawings illustrate specific exemplary embodiments in which the application may be practiced. The detailed description, including the drawings, describes these embodiments in sufficient detail to enable those skilled in the art to practice the application. Those skilled in the art may further utilize other embodiments of the application, and make logical, mechanical, and other changes without departing from the spirit or scope of the application. Readers of the following detailed description should, therefore, not interpret the description in a limiting sense, and only the appended claims define the scope of the embodiment of the application.

In this application, the use of the singular includes the plural unless specifically stated otherwise. In this application, the use of “or” means “and/or” unless stated otherwise. Furthermore, the use of the term “including” as well as other forms such as “includes” and “included” is not limiting. In addition, terms such as “element” or “component” encompass both elements and components including one unit, and elements and components that include more than one subunit, unless specifically stated otherwise. Additionally, the section headings used herein are for organizational purposes only, and are not to be construed as limiting the subject matter described.

As used herein, spatially relative terms, such as “beneath”, “below”, “above”, “over”, “on”, “upper”, “lower”, “left”, “right”, “vertical”, “horizontal”, “side” and the like, may be used herein for ease of description to describe one element or feature's relationship to another element(s) or feature(s) as illustrated in the Figures. The spatially relative terms are intended to encompass different orientations of the device in use or operation in addition to the orientation depicted in the Figures. The device may be otherwise oriented (rotated 90 degrees or at other orientations) and the spatially relative descriptors used herein may likewise be interpreted accordingly. It should be understood that when an element is referred to as being “connected to” or “coupled to” another element, it may be directly connected to or coupled to the other element, or intervening elements may be present.

As mentioned above, electronic components are generally mounted onto a substrate of an electronic device after a reflowing process of a solder paste which later forms solder bumps. To be more specific, a typical solder paste may include flux and a metal solder material. During the reflowing process, the metal solder material may melt and be reshaped, and at the same time, the flux may be activated and vaporized. The vaporized flux and/or other gases in an environment where the electronic device is placed may be trapped within the solder paste, thereby forming voids within the solder paste which later transforms into solder bumps. This may adversely affect bonding performance between the substrate and the electronic components and increase short-circuit risks.

To address this issue, a new method for forming an electronic device is provided. The new method introduces an inert atmosphere to reflow a solder paste between a substrate and at least one electronic component. The inert atmosphere has a reduced oxygen partial pressure compared with air atmosphere, which reduces surface tension of the molten solder paste during a reflowing process of the solder paste. The reduced oxygen partial pressure enables gases trapped within the solder paste to escape more easily before the solder paste gets solidified. As such, after the reflowing process, solder bumps can be formed with fewer void defects or even with no void defects, which enhances joint reliability between the substrate and the electronic components.

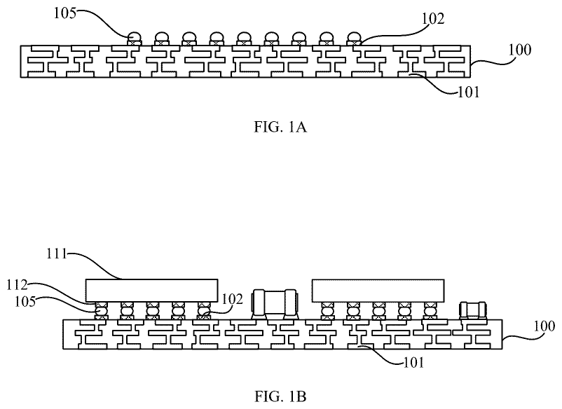

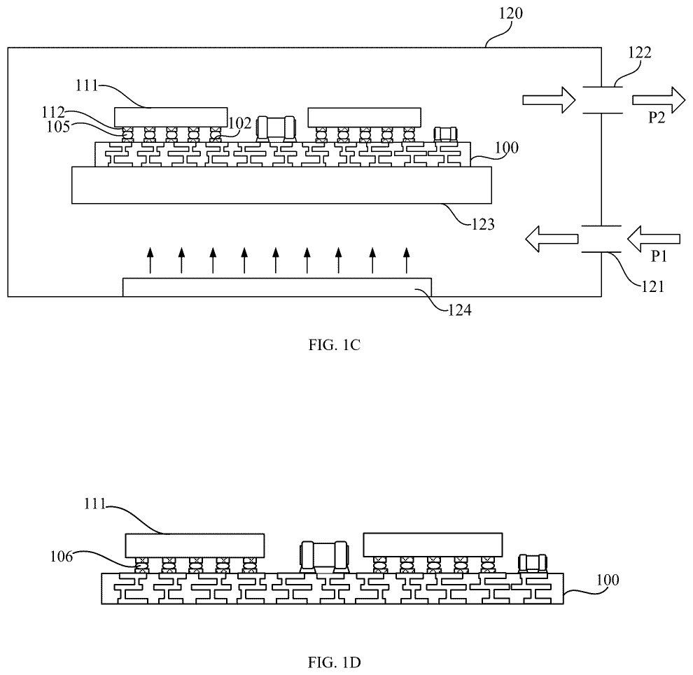

FIGS. 1A to 1D illustrate various steps of a method for forming an electronic device according to a first embodiment of the present application.

As shown in FIG. 1A, a substrate 100 is provided with embedded interconnect wires 101. The substrate 100 includes a front surface, which may serve as a platform where electronic component(s) can be mounted, and a back surface opposite to the front surface. The interconnect wires 101 may be formed between and through the substrate 100. Thus, the electronic component(s) and other structures on either one surface or both surfaces of the substrate 100 may be electrically coupled with each other to form an integrated electronic system. In some embodiments, a first set of conductive pads 102 can be formed on the front surface of the substrate 100 for the mounting of the electronic component(s). It also can be appreciated that the first set of conductive pads 102 may be exposed portions of interconnect wires 101 formed within the substrate 100.

Next, a solder paste 105 is dispensed on each of the first set of conductive pads 102 for the mounting of the electronic component(s). The solder paste 105 may include a metal solder material and flux. In some embodiments, the metal solder material may include a metal material or a combination of metal materials. It can be appreciated that a combination of metal and non-metal materials may also be provided within the metal solder. To be more specific, the metal material(s) may be Al, Sn, Ni, Au, Ag, lead (Pb), bismuth (Bi), Cu, or combinations thereof. In some embodiments, the metal solder material may include metal powders, for example, sintered metal powders. In some other embodiments, an adhesive material may be further provided to glue the metal powders. The adhesive material should be sticky enough to glue the metal powders together before, during and after a subsequent heating process of the solder paste 105. In other words, the adhesive material should not volatilize completely during the heating process of the solder paste 105. In addition, the adhesive material may include a thermal conductive material, which allows for an efficient convection heat transfer within the solder paste 105 during the heating process.

Furthermore, the flux within the solder paste 105 may be used to facilitate a subsequent heating process of the solder paste 105, thereby enabling sufficient electrical connection between the substrate 100 and the electronic component(s) mounted thereon. In some embodiments, the flux may include rosin or a water-soluble material made up of organic components and glycol bases. In some embodiments, the flux may be coated onto surfaces, for example, bottom surfaces or whole spherical surfaces of the metal solder material. In some other embodiments, the flux may be mixed with the metal solder material to form a solder paste mixture, which further enhances the convection heat transfer from the flux to the metal solder material.

Next, as shown in FIG. 1B, at least one electronic component 111 is provided. In some embodiments, the electronic component(s) 111 may include various types of electronic modules, such as semiconductor chips, resistors, capacitors or the like. In an alternative embodiment, the at least one electronic component 111 may include a semiconductor package. It can be appreciated that the electronic component(s) 111 may be arranged and sized according to actual needs of the electronic device to be formed. In the embodiment shown in FIG. 1B, the electronic components 111 with different types, different sizes or different materials may be included in a single electronic device, depending on actual needs.

Next, the at least one electronic component 111 is disposed onto the front surface of the substrate 100. To be more specific, the at least one electronic component 111 may include a second set of conductive pads 112 on its back surface. Each of the second set of conductive pads 112 is aligned with one of the first set of conductive pads 102 with the solder paste 105 disposed therebetween. In some other embodiments, an additional solder paste may be attached or dispensed on the second set of conductive pads 112. The at least one electronic component 111 may then be disposed on the front surface of the substrate 100 with the solder paste 105 and the additional solder paste disposed between the first and second set of conductive pads 102, 112.

Next, as shown in FIG. 1C, a reflowing process is conducted to the solder paste 105 by a heating process within a reflowing chamber 120. During the reflowing process, the substrate 100 may be placed on a platform 123 within the reflowing chamber 120. A gas supply may be fluidly connected to the reflowing chamber 120 to apply an inert gas P1 into the reflowing chamber 120 to reach the substrate 100 and the solder paste 105 through an inlet 121. Thus, compared with air atmosphere, an oxygen partial pressure within the reflowing chamber 120, i.e., around the substrate 100 and the solder paste 105, can be reduced by the inert gas P1 which generally contains no oxygen. Also, a vacuum source may be fluidly connected to the reflowing chamber 120 to pump air and other gases out of the reflowing chamber 120 through an outlet 122 to apply a vacuum pressure within the reflowing chamber 120, i.e., vacuumize the reflowing chamber 120. In other words, the air atmosphere in the reflowing chamber can be gradually replaced with the inert atmosphere. The inert gas P1 and the vacuum pressure together create a reflowing atmosphere within the reflowing chamber 120 to improve the reflowing process of the solder paste 105, as elaborated later. In some embodiments, an input flow rate of the inert gas introduced into the reflowing chamber 120 through the inlet 121 may be lower than an output flow rate through the outlet 122, such that the atmosphere in the reflowing chamber during the reflowing process may have a relatively low pressure.

In some embodiments, the inlet 121 and the outlet 122 may be arranged on the same side of the reflowing chamber 120, as shown in FIG. 1C. In some other embodiments, the inlet 121 and the outlet 122 may be arranged on two opposite sides of the reflowing chamber 120, which may help create a more uniform atmosphere inside the reflowing chamber 120.

Still referring to FIG. 1C, a heating device 124 may be used to apply heat energy to the substrate 100 to reflow the solder paste 105. In some embodiments, such as in the embodiment shown in FIG. 1C, infrared radiation may be applied to heat and reflow the solder paste 105 within the reflowing atmosphere. Thus, an infrared radiation source 124 may be disposed within the reflowing chamber to apply infrared radiation to heat and reflow the solder paste 105. During the infrared radiation process, the flux within the solder paste 105 may receive the radiation energy and convert it into heat, which leads to a high temperature rise of the flux, e.g., to a temperature higher than a melting temperature of the metal solder material within the solder paste 105. With the temperature rise of the flux, a part of the heated flux may volatilize first, and the heat generated in the flux may be convectively transferred to the metal solder material, which brings about a temperature rise of the metal solder material. In addition, the metal solder material itself may also absorb the radiation energy, which results in a further temperature rise of the metal solder material. Then the temperature of the metal within the metal solder may rise over its melting temperature, which induces the metal to melt and enables the metal solder material to be reshaped in a molten state. In some other embodiments, various types of heaters capable of generating radiation heat may be used as the heating device 124. For example, a quartz heater, a ceramic heater, a halogen heater or the like may be used as the heating device 124 for heat radiation.

As aforementioned, during the infrared radiation process, gas in the environment and/or a residual gas of the vaporized flux may be temporarily trapped within the molten solder paste 105 during or after the rapid heating process. Here, in the embodiment shown in FIG. 1C, the reflowing atmosphere within the reflowing chamber 120 may facilitate the gas trapped within the molten solder paste 105 to escape out of the solder paste 105 easily.

To be more specific, in some embodiments, the inert gas P1 may be applied to the solder paste 105 to reduce the oxygen partial pressure around the substrate 100 and the solder paste 105 before applying the infrared radiation. During the infrared radiation heating process, the reduced oxygen partial pressure may result in a decrease in polar bonds within the solder paste 105, thereby reducing a surface tension on a surface of the molten solder paste 105. In this way, the gas trapped within the molten solder paste 105 may be more easily to escape out of the solder paste 105. The inert gas P1 may be continuously applied during or even after the infrared radiation heating process, as long as the solder paste 105 is still kept at a reflow temperature. The reflow temperature ensures the solder paste 105 to keep in the molten state such that the voids within the solder paste 105 can be removed. In some embodiments, the inert gas P1 may include nitrogen, and the nitrogen within the reflowing atmosphere has a partial pressure of 0.3 MPa˜1 MPa during the reflowing of the solder paste 105 when the reflowing atmosphere stabilizes. In some other embodiments, the inert gas may include other types such as helium. The inert gas P1 may be applied with a sufficient duration, preferably from 30 seconds to 120 seconds, to ensure effective reflowing of the solder paste 105. In some embodiments, the vacuum source may be turned on to pump a portion of the gas out of the reflowing chamber 120, which prevents a pressure increase within the reflowing chamber 120.

Still referring to FIG. 1C, during the infrared radiation process, the vacuum source may continuously be turned on to pump the previously introduced nitrogen, vaporized flux and air P2 out of the reflowing chamber 120 through the outlet 122 to reach a vacuum pressure within the reflowing chamber 120. In some embodiments, the vacuum pressure may be less than 5 mtorr to provide a sufficient vacuum environment, for example. At the same time, the vacuum pressure may create a pressure difference between an interior of the voids within the solder paste 105 and the vacuum environment outside the solder paste 105. As such, the gas trapped within the voids may be expelled out of the solder paste 105. Thus, the vacuum pressure and the inert gas may have a joint effect on reducing voids within the solder paste 105. In addition, by removing the gas within the voids, heat may be more effectively transferred to the substrate 100 and the solder paste 105 without the blocking of gas which has a relatively low thermal conductivity, thereby ensuring a uniform heat distribution across the solder paste 105. Furthermore, the vacuum environment around the solder paste 105 eliminates convective currents resulted from the gas flow, thereby reducing potential disturbance to heat transfer during the reflowing process of the solder paste 105 and providing a more uniform heat distribution across the solder paste 105. As such, although the solder paste 105 absorbs radiation energy strongly and gets heated rapidly during a fast reflowing processing such as the infrared radiation process, the uniformity of the reflowing process may be improved and hotspots generated during the reflowing process may be reduced. In some embodiments, the vacuum pressure may be applied even after the infrared radiation heating process, while the solder paste 105 maintains in a high temperature such as above its melting temperature, as elaborated below.

When the solder paste 105 is exposed to or maintained in the reflowing atmosphere, it should keep at a reflow temperature, which ensures the solder paste 105 to keep in the molten state such that the voids within the solder paste 105 can be removed. In some preferred embodiments, the reflow temperature may range from 200° C. to 240° C., thereby ensuring sufficient wetting of the solder paste 105, i.e., the metal solder material, on surfaces of the first and second sets of conductive pads 102, 112.

In summary, the process of applying the inert gas P1, the process of applying the vacuum pressure and the heating process of the solder paste 105 may be flexible based on actual needs of the reflowing process of the solder paste 105. As mentioned above, in some embodiments, the inert gas P1 may be introduced into the reflowing chamber 120 before the vacuum pressure is applied. It can be appreciated that the inert gas P1 may also be introduced into the reflowing chamber 120 when the vacuum source is turned on to pump gas out of the reflowing chamber 120, such that the oxygen partial pressure within the reflowing chamber 120 may also be reduced. In some embodiments, the inert gas P1 may be introduced before the heating process of the solder paste 105. As such, the solder paste 105 can be reflowed by the heating process within the inert atmosphere, which reduces the surface tension of the molten solder paste 105 to facilitate easy removal of the voids within the solder paste 105. During the heating process, the inert gas P1 may or may not be introduced into the reflowing chamber 120. For example, the inert gas P1 may only be introduced for a certain period, or be introduced in a gradually decreasing flow rate. Moreover, the gas within the reflowing chamber 120 may also be pumped out during the heating process to achieve a vacuum pressure, such that the voids within the solder paste 105 can be effectively expelled.

In some other embodiments, the inert gas P1 and/or vacuum pressure may also be applied after the infrared radiation heating process. In this case, an additional heater may be provided within the platform 123 to preserve or provide heat energy and slow down a cooling speed of the solder paste 105, such that the solder paste 105 may be maintained at the reflow temperature within the reflowing atmosphere, which may be approximately the same or slightly lower than the temperature of the solder paste 105 during the infrared radiation heating process. In some embodiments, a carrier with a heat transfer blocking top layer may be used instead of the heater, to avoid fast cooling of the substrate 100 and the solder paste 105. In this way, the voids within the solder paste 105 which are generated during the infrared radiation process can be sufficiently reduced.

After the solder paste 105 is sufficiently reflowed, the vacuum pressure and/or the inert gas P1 may no longer be applied to the substrate 100. The solder paste 105 may be cooled to a temperature lower than the reflow temperature, such that the solder paste 105 is solidified into solder bumps to form electrical joints between the substrate 100 and the at least one electronic component 111. It can be appreciated that external gases may be introduced into the reflowing chamber 120 to raise the pressure that the substrate 100 and the reflowed solder paste 105 are exposed to, thereby completing the vacuum reflow process. In some preferred embodiments, a duration that the pressure is gradually increased after the vacuum reflow process may be the same as or longer than (for example, two or three times of) the duration that the vacuum pressure is applied to the substrate 100. Alternatively, the substrate 100 and the reflowed solder paste 105 may also be exposed to an atmosphere in the external environment after the vacuum reflow process. In some other embodiments, the solder paste 105 may be cooled and solidified into solder bumps when the inert gas P1 and the vacuum pressure are applied to the substrate 100.

Finally, as shown in FIG. 1D, the solder paste 105 is solidified into solder bumps 106 to form the electrical joints between the substrate 100 and the at least one electronic component 111, thereby forming an electronic device. By applying the inert gas P1 and the vacuum pressure, the reflowing process of the solder paste 105 may be conducted more uniformly and thoroughly. The solder bumps 106 can be formed with uniform structures and reduced void defects, which improves joint reliability between the at least one electronic component 111 and the substrate 100.

In some embodiments, the flux may volatilize completely, allowing the reflowed metal solder to form electrical joints. In some other embodiments, only a part of the flux may volatilize, and finally the remaining flux may be removed from the metal solder, for example, by a cleaning agent. In some alternative embodiments, finally the remaining flux and the metal solder material may melt together to form electrical joints between the electronic component 111 and the substrate 100.

Afterwards, an encapsulant layer may be formed on the substrate 100 to encapsulate the at least one electronic component 111 and the solder bumps 106, therefore forming an electronic package. In some other embodiments, the method for forming the electronic device may not include the process of forming the encapsulant layer.

In the embodiment shown in FIG. 1C, more than one electronic component 111 is disposed on the substrate 100, and the electronic components 111 have different sizes, compositions or structures. In this case, a heating device 124, such as an infrared radiation source may be disposed underneath the substrate 100 and the platform 123 to apply infrared radiation to the solder paste 105 and the substrate 100 from a bottom side of the platform 123. As such, the substrate 100 and the solder paste 105 may be heated in a more uniform way to reduce warpage issues and defects in the formed solder bumps 106.

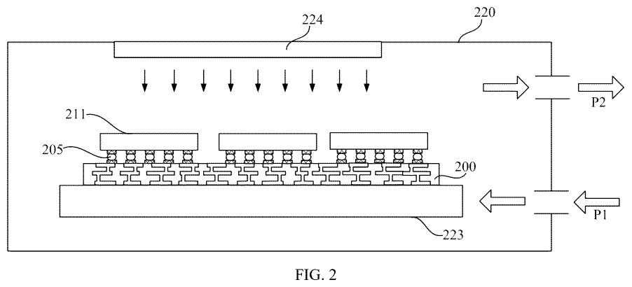

In some other embodiments such as a second embodiment shown in FIG. 2, electronic components to be mounted on a substrate may have a same size, composition and structure. In this case, an infrared radiation source 224 may be disposed within a reflowing chamber 220 above the substrate 200 and the platform 223 to apply infrared radiation to the solder paste 205 from a top side of the electronic components 211. As such, the solder paste 205 may absorb radiation energy more directly without blocking of the substrate 200 and the platform 223.

In some embodiments, the method can be used in forming an electronic device with a reduced size and complex structures, such as a system-in-package (SIP) device with various electronic components. In some other embodiment, the electronic device can be applied in any devices which desire reduced warpage issues and improved reliability of the electrical joints. The electronic device may also be a double-sided electronic device, and accordingly, a back surface of the substrate may also serve as another platform where electronic component(s) may be mounted on via a solder paste. The solder paste on the front surface and the back surface of the substrate may be reflowed by infrared radiation and within a reflowing atmosphere created via the inert gas and the vacuum pressure to form electrical joints between the electronic component(s) and the substrate.

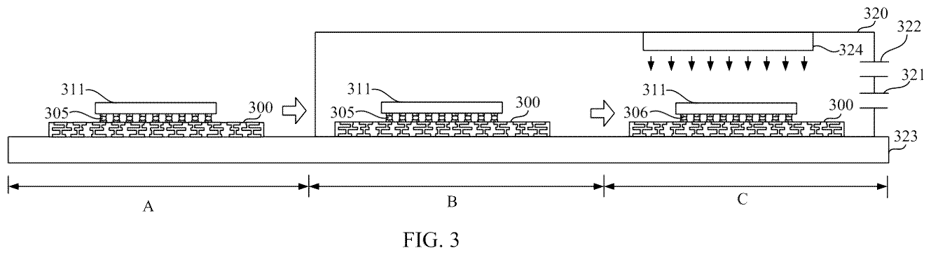

FIG. 3 illustrates an apparatus for forming an electronic device according to a third embodiment of the present application. In particular, a reflowing process of a solder paste within the electronic device may be implemented using the apparatus. Details of a process of forming the electronic device may be similar to the method for forming the electronic device illustrated in FIGS. 1A to 1D, or FIG. 2.

As shown in FIG. 3, the apparatus may include three sequentially arranged zones, namely, a first zone A, a second zone B and a third zone C, which are used to implement a reflowing process of a solder paste 305 between a substrate 300 and at least one electronic component 311. The apparatus further includes a platform 323 for placing the substrate 300. The platform 323 is in a form of an integrated piece across the first zone A, the second zone B and the third zone C. In some embodiments, a main chamber may be provided to include all of the three zones or even more additional zones as desired, which may prevent contaminants from entering into the apparatus, thereby protecting the substrate 300 and structures thereon during the reflowing process.

In some embodiments, the first zone A may be a preparation region before a reflowing process. In the first zone A, the at least one electronic component 311 may be disposed onto the substrate 300 via a solder paste 305, the details of which may refer to the embodiment shown in FIGS. 1A and 1B.

The second zone B and the third zone C are used for accommodating a reflowing chamber 320. The reflowing chamber 320 may be arranged on the platform 323 and extend from the second zone B to the third zone C. In some other embodiments, the platform 323 may extend through the reflowing chamber 320. The reflowing chamber 320 is used for accommodating the substrate 300 during the reflowing process of the solder paste 305 and also providing a reflowing atmosphere for the reflowing process. To be more specific, the reflowing chamber 320 is fluidly connected with a vacuum source, such as a vacuum pump, which is used for pumping gases P2 out and applying a vacuum atmosphere within the reflowing chamber 320 through an outlet 322. A gas supply may also be fluidly connected with the reflowing chamber 320 to apply an inert gas P1 to the substrate 300 and the solder paste 305 through an inlet 321. Moreover, a heating device 324 may be disposed within a portion of the reflowing chamber 320, namely, the third zone C. The heating device 324 is used for heating the substrate 300 and the solder paste 305 to reflow the solder paste 305. The heating device 324 may be arranged above the platform 323 (such as shown in FIG. 3) or below the platform 323 (such as shown in FIG. 2). More details of the reflowing chamber 320 and functions may be similar to the reflowing chamber 120 or 220 illustrated with respect to the first and second embodiments shown in FIG. 1C and FIG. 2.

In some embodiments, when forming an electronic device, the substrate 300 may first be placed on the platform 323. The at least one electronic component 311 may be disposed onto the substrate 300 via a solder paste 305 within the first zone A. Next, the substrate 300 may be transported into the reflowing chamber 320. To be more specific, the substrate 300 may first be disposed within the reflowing chamber 320 within the second zone B to prepare and set up the reflowing process. Next, the substrate 300 may be transported to the third zone C to reflow the solder paste 305 through a heating process conducted via the heating device 324. The inert gas P1 and the vacuum pressure may be applied to the reflowing chamber 320 when the substrate 300 enters the second zone B, or when the substrate 300 reaches the third zone C. In some embodiments, the gas supply and the vacuum source may be turned on when the substrate 300 is within the second zone B, within the third zone C, or anytime when the substrate 300 is being transported from the second zone B to the third zone C to create the reflowing atmosphere within the reflowing chamber 320. When the substrate 300 enters the third zone C, the heating device 324 may be turned on to heat and reflow the solder paste 305 within the reflowing atmosphere, such that voids formed within the solder paste 305 can be removed during the reflowing process.

In some embodiments, the reflow temperature of the solder paste 305 may keep at a range from 200° C. to 240° C. A heater may be provided to preserve heat energy or slow down a cooling speed of the solder paste 305, such that the solder paste 305 may be maintained at the reflow temperature within the reflowing atmosphere. In some embodiments, a carrier with a heat transfer blocking top layer may be used instead of the heater, to avoid for fast cooling of the substrate 300 and the solder paste 305. In this way, the voids within the solder paste 305 which are generated during the heating process can be reduced sufficiently when the solder paste 305 is continuously kept in a molten state.

In some embodiments, a conveyor may extend through the first zone A, the second zone B and the third zone C. During the reflowing process, the conveyor can transport the substrate 300 from the first zone A through the second zone B to the third zone C. The conveyor may include a belt or a carrier on a rail to transport the substrate 300 with a controlled speed. It can also be appreciated that the apparatus may not include a conveyor and the substrate 300 may be transported by a manual operation.

In some other embodiments, the apparatus may not include the second zone B. The reflowing chamber 320 is only arranged within the third zone C. The substrate 300 may be transported from the first zone A directly to the third zone C where the solder paste 305 is being heated and reflowed.

In an alternative embodiment, the heating device 324 may be arranged in the first zone A. In this way, the solder paste 305 may be heated by the heating device 324 to a reflowing temperature within the first zone A. Next, the substrate 300 may be transported to the reflowing chamber 320 disposed within the second zone B and/or the third zone C to continue the reflowing process of the solder paste 305. When the substrate 300 is accommodated within the reflowing chamber 320, the solder paste 305 may still be maintained at a high reflowing temperature, which is slightly lower than the temperature of the solder paste 305, e.g., 70% to 90% of the temperature of the solder paste 305, during the heating process in the first zone A. As such, the solder paste 305 may still be kept in the molten state. In some embodiments, the temperature of the solder paste 305 during the heating process in the first zone A may be 250° C., and the reflowing chamber 320 may be maintained at a temperature of 200° C. In this way, the solder paste 305 may be maintained at a temperature between 200° C. and 250° C. when the substrate 300 is disposed within the reflowing chamber 320, such that the voids formed within the solder paste 305 may be reduced within the reflowing atmosphere created by the inert gas and the vacuum pressure.

Next, after a reflowing process of the solder paste 305, the solder paste 305 may be cooled and be solidified into the solder bumps 306 within the third zone C. In some other embodiments, the substrate 300 may be transported to an additional cooling zone to cool the solder paste 305 and solidify the solder paste 305 into the solder bumps 306.

While the exemplary method for forming an electronic device of the present application is described in conjunction with corresponding figures, it will be understood by those skilled in the art that modifications and adaptations to the method for forming an electronic device may be made without departing from the scope of the present invention.

Various embodiments have been described herein with reference to the accompanying drawings. It will, however, be evident that various modifications and changes may be made thereto, and additional embodiments may be implemented, without departing from the broader scope of the invention as set forth in the claims that follow. Further, other embodiments will be apparent to those skilled in the art from consideration of the specification and practice of one or more embodiments of the invention disclosed herein. It is intended, therefore, that this application and the examples herein be considered as exemplary only, with a true scope and spirit of the invention being indicated by the following listing of exemplary claims.

1. A method for forming an electronic device, the method comprising:
providing a substrate;
disposing at least one electronic component on the substrate via a solder paste;
applying an inert atmosphere to the substrate and the solder paste, wherein the inert atmosphere has a reduced oxygen partial pressure compared with air atmosphere; and
reflowing the solder paste by a heating process within the inert atmosphere to reduce voids formed within the solder paste during the reflowing of the solder paste.

2. The method of claim 1, wherein reflowing the solder paste by a heating process comprises:
applying infrared radiation to heat and reflow the solder paste.

3. The method of claim 2, wherein disposing at least one electronic component on the substrate via a solder paste comprises:
disposing more than one electronic component on the substrate, wherein the more than one electronic components have different sizes or materials; and
wherein the infrared radiation is applied to the substrate and the solder paste from a bottom surface of the substrate.

4. The method of claim 2, wherein disposing at least one electronic component on the substrate via a solder paste comprises:
disposing more than one electronic component on the substrate, wherein the more than one electronic components have a same size and material; and
wherein the infrared radiation is applied to the more than one electronic component and the solder paste from a top surface of the more than one electronic component.

5. The method of claim 1, wherein applying an inert atmosphere to the substrate and the solder paste is performed before reflowing the solder paste by a heating process.

6. The method of claim 1, wherein applying an inert atmosphere to the substrate and the solder paste is performed simultaneously with reflowing the solder paste by a heating process.

7. The method of claim 1, wherein the inert atmosphere has a pressure of less than 5mtorr during the reflowing of the solder paste.

8. The method of claim 1, wherein applying an inert atmosphere to the substrate and the solder paste comprises:
placing the substrate with the solder paste in a reflowing chamber; and
filling in the reflowing chamber with an inert gas to form the inert atmosphere.

9. The method of claim 8, wherein the inert gas comprises nitrogen.

10. The method of claim 9, wherein the nitrogen within the inert atmosphere has a partial pressure of 0.3 MPa˜1 MPa during the reflowing of the solder paste.

11. The method of claim 8, wherein after applying an inert atmosphere to the substrate and the solder paste, the method further comprises:
vacuumizing the reflowing chamber.

12. The method of claim 1, further comprising:
solidifying the solder paste into solder bumps between the substrate and the at least one electronic component.

13. An apparatus for forming an electronic device, the apparatus comprising:
a platform configured for placing a substrate, wherein the substrate is disposed with at least one electronic component via a solder paste;
a heating device configured for heating the substrate and the solder paste to reflow the solder paste;
a reflowing chamber disposed on the platform and configured for reflowing the solder paste when the substrate is disposed within the reflowing chamber;
a vacuum source in communication with the reflowing chamber and configured for applying a vacuum pressure to the substrate and the solder paste when the substrate is disposed within the reflowing chamber; and
a gas supply in communication with the reflowing chamber and configured for applying an inert gas to the substrate and the solder paste when the substrate is disposed within the reflowing chamber, wherein the vacuum pressure and the inert gas applied to the solder paste and the substrate reduce voids formed within the solder paste during the reflowing of the solder paste within the reflowing chamber.

14. The apparatus of claim 13, wherein the heating device comprises an infrared radiation source.
